(19) United States
(12) Patent Application Publication
(10) Pub. No.: US 2024/0395688 A1
(43) Pub. Date: Nov. 28, 2024

(54) ELECTRONIC COMPONENT

(71) Applicant: Murata Manufacturing Co., Ltd., Kyoto (JP)

(72) Inventors: Takashi KAWANAMI, Kyoto (JP); Takayuki TOMITA, Kyoto (JP); Toshio SUDA, Kyoto (JP)

(21) Appl. No.: 18/661,941

(22) Filed: May 13, 2024

(30) Foreign Application Priority Data
May 23, 2023 (JP) 2023-084830

(51) Int. Cl. H01L 23/498; H01L 23/00; H01L 23/14; H01L 23/31

(52) U.S. Cl. CPC H01L 23/49838; H01L 23/145; H01L 23/3107; H01L 24/13; H01L 24/16; H01L 2224/13147; H01L 2224/1357; H01L 2224/16227; H01L 2924/1579

(57) ABSTRACT

In an electronic component, a package includes a resin portion and a plurality of land electrodes. The resin portion has a first main surface and a second main surface facing each other in a predetermined direction and covers an IC chip. The plurality of land electrodes includes one first land electrode and three or more second land electrodes, which are the remaining land electrodes other than the first land electrode. The area of the first land electrode is larger than the area of each of the three or more second land electrodes in plan view from the predetermined direction. The plan-view shape of the first land electrode is different from the plan-view shapes of the three or more second land electrodes in plan view from the predetermined direction.

### CROSS REFERENCE TO RELATED APPLICATION

This application claims priority from Japanese Patent Application No. 2023-084830 filed on May 23, 2023. The content of this application is incorporated herein by reference in its entirety.

### BACKGROUND OF THE DISCLOSURE

### 1. Field of the Disclosure

The present disclosure relates generally to an electronic component, and more particularly to an electronic component provided with an IC chip and a package.

### 2. Description of the Related Art

Japanese Unexamined Patent Application Publication No. 2006-303029 (hereinafter referred to as “Patent Document 1”) discloses a semiconductor device provided with a semiconductor element (IC chip), a resin (resin portion), a plurality of outer electrodes, and four reinforcing pads.

In the semiconductor device disclosed in Patent Document 1, the shape of a specific reinforcing pad, which is one reinforcing pad of the four reinforcing pads, is different from the shapes of the other reinforcing pads so that the direction of the semiconductor device can be specified.

Patent Document 1 describes that since the shape of the specific reinforcing pad is different from that of the other reinforcing pads, the direction of the semiconductor device can be recognized from an image of the backside of the semiconductor device captured by a camera during the mounting process without separately forming an identification mark.

### SUMMARY OF THE DISCLOSURE

In the semiconductor device (electronic component) disclosed in Patent Document 1, since the specific reinforcing pad is smaller than the other reinforcing pads, it may be difficult to identify the direction by image recognition, and it may reduce the mounting strength to a mounting board.

It is a possible benefit of the present disclosure to provide an electronic component capable of improving the direction identifiability in the mounting process to a mounting board and capable of suppressing the reduction of mounting strength to the mounting board.

An electronic component according to one aspect of the present disclosure includes an IC chip and a package. The package covers the IC chip. The package includes a resin portion and a plurality of land electrodes. The resin portion has a first main surface and a second main surface facing each other in a predetermined direction, and covers the IC chip. The plurality of land electrodes is exposed from the second main surface of the resin portion. The plurality of land electrodes includes one first land electrode and three or more second land electrodes, which are the remaining land electrodes other than the first land electrode. The area of the first land electrode is larger than the area of each of the three or more second land electrodes in plan view from the predetermined direction. The plan-view shape of the first land electrode is different from the plan-view shapes of the three or more second land electrodes in plan view from the predetermined direction.

The electronic component according to the above aspect of the present disclosure can improve the direction identifiability in the mounting process to the mounting board, and can suppress the reduction of mounting strength to the mounting board.

### BRIEF DESCRIPTION OF THE SEVERAL VIEWS OF THE DRAWINGS

FIG. 1 is a partially omitted plan view of an electronic component according to Embodiment 1;

FIG. 2 is a cross-sectional view taken along line II-II of FIG. 1, with respect to the electronic component according to Embodiment 1;

FIG. 3 is a bottom view of the electronic component according to Embodiment 1;

FIG. 4 is a plan view of the electronic component according to Embodiment 1;

FIG. 5 is a circuit diagram of the electronic component according to Embodiment 1;

FIG. 6 is a partially cutaway plan view of a mounting board on which the electronic component according to Embodiment 1 is to be mounted;

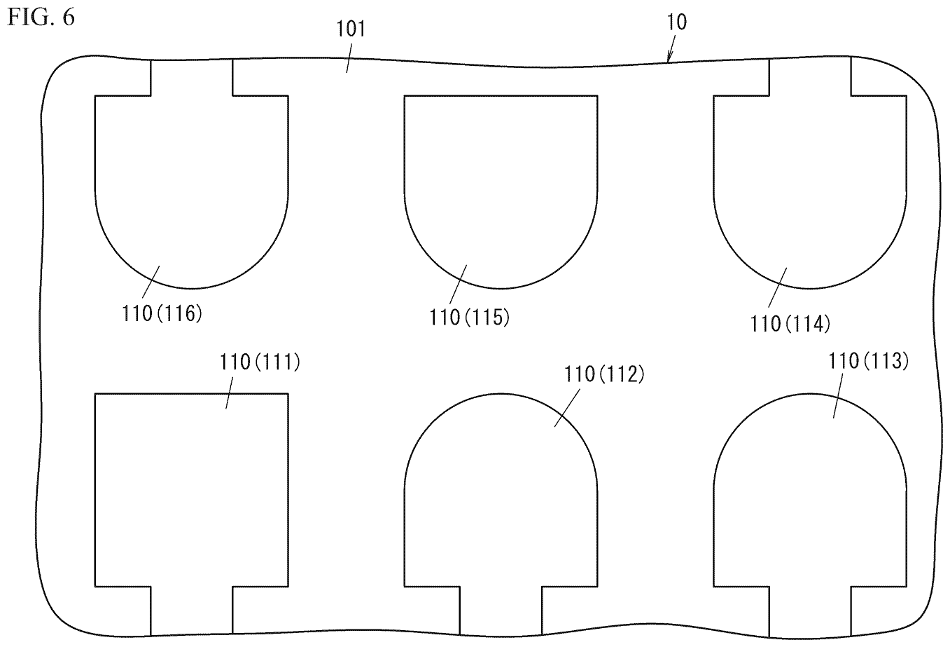

FIG. 7 is a partially cutaway cross-sectional view of a high-frequency module provided with the electronic component according to Embodiment 1 and the mounting board;

FIG. 8 is a cross-sectional view of an electronic component according to Embodiment 2;

FIG. 9 is a partially omitted plan view of an electronic component according to Embodiment 3;

FIG. 10 is a cross-sectional view taken along line X-X line of FIG. 9, with respect to the electronic component according to Embodiment 3;

FIG. 11 is a bottom view of the electronic component according to Embodiment 3;

FIG. 12 is an equivalent circuit diagram of the electronic component according to Embodiment 3;

FIG. 13 is a partially cutaway plan view of a mounting board on which the electronic component according to Embodiment 3 is to be mounted;

FIG. 14 is a partially cutaway cross-sectional view of a high-frequency module provided with the electronic component according to Embodiment 3 and the mounting board;

FIG. 15 is a bottom view of an electronic component according to Variation 1;

FIG. 16 is a bottom view of an electronic component according to Variation 2;

FIG. 17 is a bottom view of an electronic component according to Variation 3;

FIG. 18 is a bottom view of an electronic component according to Variation 4;

FIG. 19 is a bottom view of an electronic component according to Variation 5;

FIG. 20 is a bottom view of an electronic component according to Variation 6;

FIG. 21 is a bottom view of an electronic component according to Variation 7;

FIG. 22 is a bottom view of an electronic component according to Variation 8;

FIG. 23 is a bottom view of an electronic component according to Variation 9; and

FIG. 24 is a bottom view of an electronic component according to Variation 10.

### DETAILED DESCRIPTION OF THE DISCLOSURE

Embodiments 1 to 3 and the like are described below with reference to the drawings. The drawings referred to in the following embodiments and the like are schematic diagrams, and the sizes and thicknesses of the components in the drawings do not necessarily reflect the actual dimensions, nor do the ratios of the size and the thickness between components necessarily reflect the actual dimensional ratios.

### Embodiment 1

An electronic component 1 according to Embodiment 1 will be described with reference to the drawings.

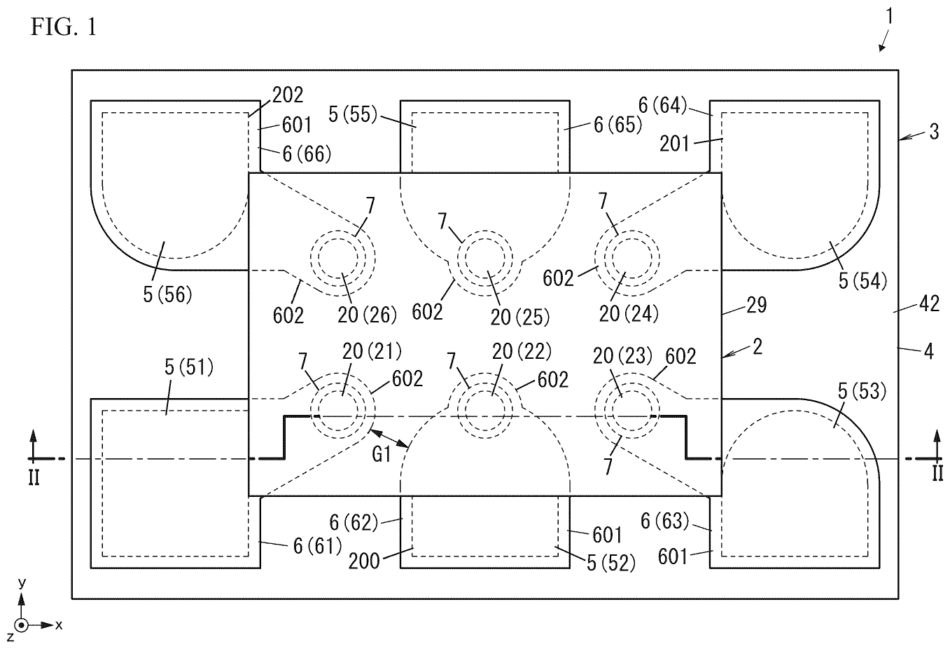

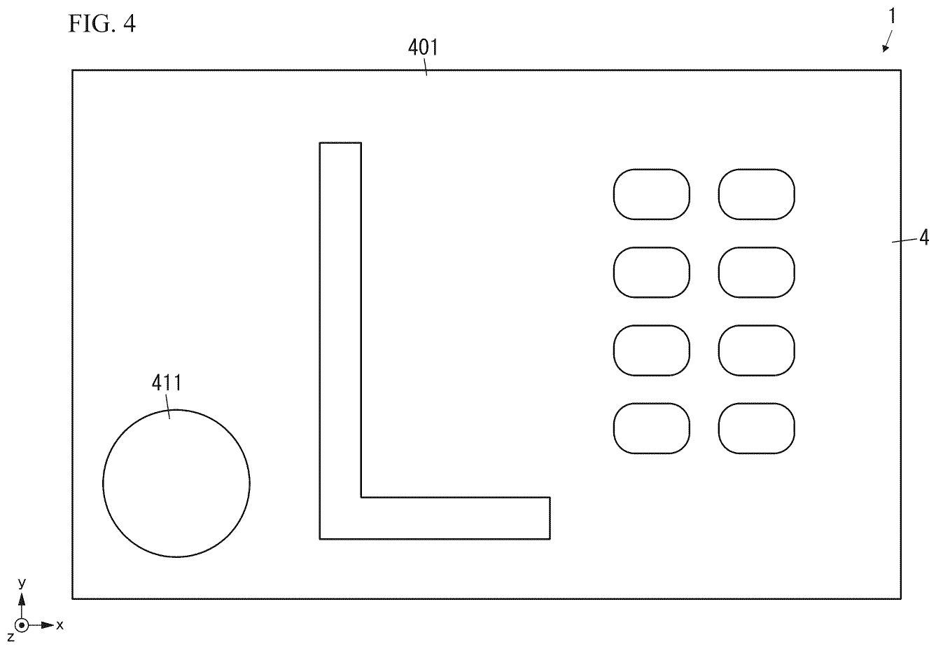

The electronic component 1 according to Embodiment 1 includes an IC chip 2 and a package 3, as shown in FIGS. 1 to 4. The electronic component 1 is an electronic component for RF (Radio Frequency). The frequency of the RF in the present disclosure is, for example, 500 MHz or higher. The electronic component for RF is used, for example, in a communication device. The communication device is, for example, a cellular phone (for example, a smart phone), but may also be, for example, a wearable device (for example, a smart watch) or the like.

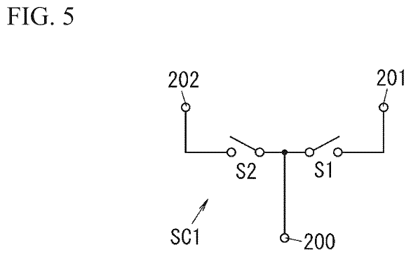

The circuit configuration of the electronic component 1 is described below with reference to FIG. 5, followed by a description of the configuration of the electronic component 1.

### (1) Circuit Configuration of Electronic Component

The electronic component 1 is, for example, an SPDT (single-pole double-throw) type switch for high frequency. More specifically, the electronic component 1 is a switch IC including a switch circuit SC1 shown in FIG. 5. The switch circuit SC1 has a common terminal 200, two switches S1 and S2, and two selection terminals 201 and 202. The switch S1 is connected between the common terminal 200 and the selection terminal 201. The switch S2 is connected between the common terminal 200 and the selection terminal 202. Each of the plurality of switches S1 and S2 is, for example, a MOSFET (Metal Oxide Semiconductor Field Effect Transistor). The IC chip 2 is, for example, a switch IC that can connect at least one or more of the plurality of selection terminals 201 and 202 to the common terminal 200. In the IC chip 2, for example, a control signal from an external circuit (for example, a signal processing circuit of a communication device such as a smartphone) is inputted from a control terminal 21, and the connection state between the common terminal 200 and the plurality of selection terminals 201 and 202 is switched according to the control signal.

### (2) Configuration of Electronic Component

### (2.1) IC Chip

The IC chip 2 is a semiconductor IC chip (also called IC die). An outer edge 29 of the IC chip 2 is rectangular in plan view from a predetermined direction. The predetermined direction is a direction extending along the z-axis when Cartesian coordinates with three mutually orthogonal x-axis, y-axis, and z-axis are specified, as shown in FIG. 1. The x-axis, y-axis, and z-axis are all virtual axes, and none of them involves any actual entity.

The IC chip 2 has a plurality (six in the example in FIG. 1) of outer terminals 20, as shown in FIG. 1. Each of the plurality of outer terminals 20 is conductive. The material of the plurality of outer terminals 20 is, for example, metal (for example, copper, a copper alloy or the like). Each of the plurality of outer terminals 20 is a columnar electrode (for example, a cylindrical or truncated conical electrode). Each of the plurality of outer terminals 20 is circular in plan view from the predetermined direction.

The plurality of outer terminals 20 includes two or more (three in the example shown in FIG. 1) high-frequency signal terminals and two or more (three in the example shown in FIG. 1) non-high-frequency signal terminals. In the example shown in FIG. 1, the two or more high-frequency signal terminals include three input/output terminals 22, 24 and 26. Each of the three input/output terminals 22, 24 and 26 is a terminal through which high-frequency signals pass. In the example shown in FIG. 1, the input/output terminal 22 of the IC chip 2 is connected to the common terminal 200, the input/output terminal 24 of the IC chip 2 is connected to the selection terminal 201, and the input/output terminal 26 of the IC chip 2 is connected to the selection terminal 202. In the example shown in FIG. 1, the two or more non-high-frequency signal terminals include a power supply terminal 23, a control terminal 21, and a ground terminal 25. The power supply terminal 23 is a terminal for inputting the power supply voltage from an external power supply to the IC chip 2. The control terminal 21 is a terminal for inputting, at the IC chip 2, a control signal from an external circuit to the IC chip 2.

### (2.2) Package

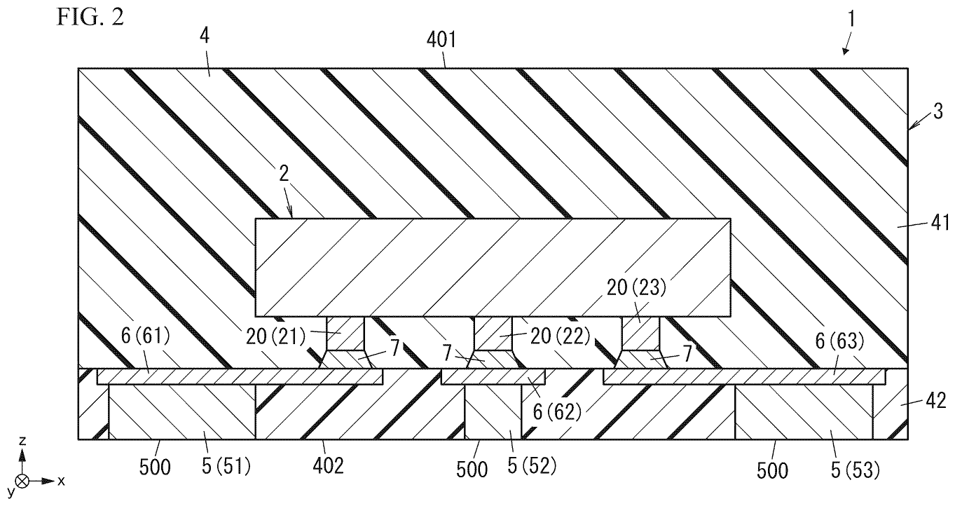

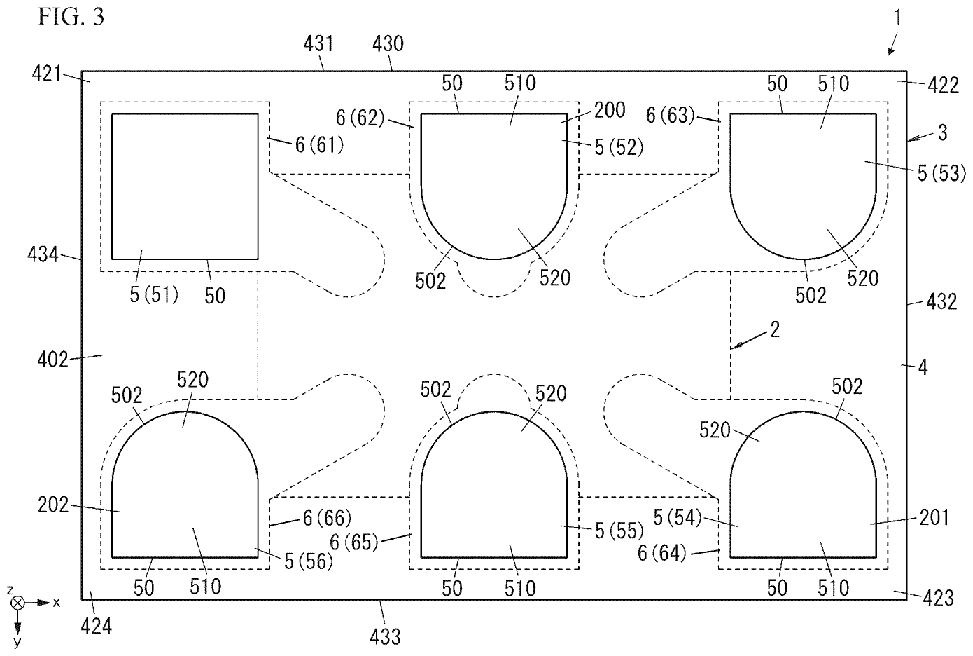

The package 3 covers the IC chip 2, as shown in FIGS. 2 and 3. The package 3 includes a resin portion 4 and a plurality (six in the example shown in FIG. 1) of land electrodes 5. The package 3 further includes a plurality (six in the example in FIG. 1) of inner electrodes 6.

### (2.2.1) Resin Portion

The resin portion 4 covers the IC chip 2. The resin portion 4 is rectangular in plan view from the predetermined direction. The resin portion 4 is larger than the IC chip 2 in plan view from the predetermined direction.

The resin portion 4 has a first main surface 401 and a second main surface 402 facing each other in the predetermined direction, and covers the IC chip 2, as shown in FIG. 2. Here, the term “facing each other” means geometrically, not physically, facing each other. An outer edge 430 of the second main surface 402 of the resin portion 4 (see FIG. 3) is rectangular in plan view from the predetermined direction. As shown in FIG. 3, the outer edge 430 of the second main surface 402 of the resin portion 4 includes two long sides 431 and 433 facing each other and two short sides 432 and 434 facing each other. The two long sides 431 and 433 are parallel to the x-axis. The two short sides 432 and 434 are parallel to the y-axis.

The resin portion 4 includes a first resin portion 41 and a second resin portion 42. The first resin portion 41 has the first main surface 401 and covers the IC chip 2. The second resin portion 42 has the second main surface 402, and the plurality of inner electrodes 6 and the plurality of land electrodes 5 are arranged in the second resin portion 42. In other words, the second resin portion 42 covers a portion of each of the plurality of inner electrodes 6 and a portion of each of the plurality of land electrodes 5 to hold the plurality of inner electrodes 6 and the plurality of land electrodes 5. In FIG. 1, the first resin portion 41 is not shown.

The first resin portion 41 has electrical insulation properties. The first resin portion 41 includes a first resin and a first filler. The first resin is, for example, an epoxy resin. The material of the first filler is, for example, silica (silicon oxide).

The second resin portion 42 has electrical insulation properties. The second resin portion 42 includes a second resin and a second filler. The second resin is, for example, an epoxy resin. The material of the second filler is, for example, glass. The first resin and the second resin may be the same or different materials. The material of the first filler and the material of the second filler may be the same or different. The filling rate of the first filler in the first resin portion 41 is determined, for example, by considering the flowability of the original resin material of the first resin portion 41 when molding the first resin portion 41. The filling rate of the second filler in the second resin portion 42 is determined, for example, by considering the flowability of the original resin material of the second resin portion 42 when molding the second resin portion 42.

The first resin and the second resin are not limited to epoxy resin, but may also be, for example, polyimide resin, acrylic resin, urethane resin or silicone resin. The materials of the first filler and the second filler are, for example, silica. The material of the filler is not limited to silica, but may also be, for example, silicon nitride, aluminum oxide, boron nitride, aluminum nitride, diamond or carbon.

The resin portion containing filler has the advantage that the larger the average particle diameter of the filler, the lower the unit cost per volume of resin material and the lower the cost; however, there is a concern that unfilled portions may occur when molding a narrow space. In Embodiment 1, each of the plurality of outer terminals 20 of the IC chip 2 is columnar and the distance between the main surface on the second resin portion 42 side of the IC chip 2 and the second resin portion 42 in the predetermined direction can be easily increased, so the average particle diameter of the first filler is larger than the average particle diameter of the second filler from the perspective of cost reduction.

### (2.2.2) A Plurality of Land Electrodes

Each of the plurality of land electrodes 5 is a terminal for mounting the electronic component 1 on a mounting board 10 or the like. The plurality of land electrodes 5 are conductive. Examples of the material of each of the plurality of land electrodes 5 include copper, a copper alloy or the like. Each of the plurality of land electrodes 5 may include, for example, a layer containing copper or a copper alloy, and a plating layer. Examples of the material of the plating layer include Ni, Pd, Au and the like.

As shown in FIGS. 2 and 3, the plurality (six in the example shown in FIG. 3) of land electrodes 5 are exposed from the second main surface 402 of the resin portion 4. In the package 3, the second main surface 402 of the resin portion 4 and a main surface 500 of the plurality of land electrodes 5 are flush with each other. The second main surface 402 of the resin portion 4 and the main surface 500 of the plurality of land electrodes 5 are flush with each other means that the step between the second main surface 402 and the main surface 500 of each land electrode 5 is less than the maximum height roughness of the second main surface 402.

The plurality of land electrodes 5 are electrically connected to the IC chip 2. The plurality of land electrodes 5 correspond to the plurality of outer terminals 20 of the IC chip 2 in a one-to-one manner, and are electrically connected to the corresponding outer terminals 20. Here, the plurality of land electrodes 5 includes a land electrode 51, a land electrode 52, a land electrode 53, a land electrode 54, a land electrode 55, and a land electrode 56. The land electrode 51 is electrically connected to the control terminal 21 of the IC chip 2. The land electrode 52 is electrically connected to the input/output terminal 22 of the IC chip 2. The land electrode 53 is electrically connected to the power supply terminal 23 of the IC chip 2. The land electrode 54 is electrically connected to the input/output terminal 24 of the IC chip 2. Land electrode 55 is electrically connected to the ground terminal 25 of the IC chip 2. The land electrode 56 is electrically connected to the input/output terminal 26 of the IC chip 2. Thus, of the plurality of land electrodes 5, the land electrodes 52, 54 and 56 are the electrodes through which high-frequency signals pass, while the land electrodes 51, 53 and 55 function as ground electrodes for alternate current.

For convenience in explaining the layout of the plurality of land electrodes 5, the land electrode 51, the land electrode 52, the land electrode 53, the land electrode 54, the land electrode 55, and the land electrode 56 may also be referred to hereinafter as a first terminal 51, a second terminal 52, a third terminal 53, a fourth terminal 54, a fifth terminal 55, and a sixth terminal 56.

In the package 3, the first terminal 51 to the sixth 56 terminal are arranged in a 2×3 matrix. The first terminal 51 is located at one corner portion 421 of four corner portions 421˜424 of the second main surface 402 of the resin portion 4. Each of the four corner portions 421˜424 of the second main surface 402 of the resin portion 4 refers to an area near but not at the apex.

A mark 411 (see FIG. 5) for determining the direction of the electronic component 1 from the first main surface 401 side is formed on the first main surface 401 of the resin portion 4.

In the package 3, with the first terminal 51 as the reference, the first terminal 51, the second terminal 52, the third terminal 53, the fourth terminal 54, the fifth terminal 55, and the sixth terminal 56 are arranged in a direction along the outer edge 430 of the resin portion 4 in the order of the first terminal 51, the second terminal 52, the third terminal 53, the fourth terminal 54, the fifth terminal 55, and the sixth terminal 56. More specifically, in the package 3, the first terminal 51, the second terminal 52, and the third terminal 53 are arranged in the order of the first terminal 51, the second terminal 52, and the third terminal 53 along one long side 431 of the two long sides 431 and 433 in the direction of the positive side of the x-axis; and the fourth terminal 54, the fifth terminal 55, and the sixth terminal 56 are arranged in the order of the fourth terminal 54, the fifth terminal 55, and the sixth terminal 56 along the other one long side 433 in the direction of the negative side of the x-axis. The first terminal 51, the second terminal 52 and the third terminal 53, which are arranged along one long side 431, are of equal pitch. The fourth terminal 54, the fifth terminal 55, and the sixth terminal 56, which are arranged along one long side 433, are of equal pitch. In the present disclosure, the term “equal pitch” does not have to be strictly equal pitch. For example, the distance between the centerline parallel to the y-axis at the first terminal 51 and the centerline parallel to the y-axis at the second terminal 52 may be 90% or more and 110% or less of the distance between the centerline parallel to the y-axis at the second terminal 52 and the centerline parallel to the y-axis at the third terminal 53.

The plurality of land electrodes 5 includes one first land electrode (land electrode 51) and five second land electrodes (land electrodes 52˜56), which are the remaining five land electrodes other than the first land electrode.

The area of the land electrode 51 is larger than the area of each of the five land electrodes 52˜56 in plan view from the predetermined direction. The plan-view shape of the land electrode 51 is different from the plan-view shape of the five land electrodes 52˜56 in plan view from the predetermined direction. The plan-view shapes of the five land electrodes 52˜56 are identical to each other.

The plan-view shape of the land electrode 51 is a rectangular shape. Here, “rectangular shape” is a square shape, but it is not limited to a square shape and can also be a non-square rectangular shape. The “rectangular shape” is not limited to shapes that are strictly rectangular, but also includes shapes in which each of the four apexes is rounded. When the land electrode 51 has a rectangular shape with each of the four apexes rounded, it has an advantage that burrs are less likely to form on the land electrode 51 in the process of forming the land electrode 51 during manufacturing. Each of the five land electrodes 52˜56 includes a first portion 510 and a second portion 520. The first portion 510 has a non-square rectangular shape in plan view. The second portion 520 is shaped so that its width becomes narrower as it goes away from the first portion 510. In each of the five land electrodes 52˜56, the first portion 510 and the second portion 520 are arranged in the order of first portion 510 and second portion 520 from the outer edge 430 of the second main surface 402 of the resin portion 4. In the direction parallel to the x-axis, the width of the first portion 510 of each of the five land electrodes 52˜56 is the same as the width of the land electrode 51. The plan-view shape of each of the five land electrodes 52˜56 has an arc-shaped portion 502.

### (2.2.3) A Plurality of Inner Electrodes

The plurality (six in the example in FIG. 1) of inner electrodes 6 are arranged in the resin portion 4. The plurality of inner electrodes 6 are connected to the IC chip 2.

The plurality of inner electrodes 6 correspond to the plurality of outer terminals 20 of the IC chip 2 in a one-to-one manner. Each of the plurality of inner electrodes 6 is electrically connected to a corresponding outer terminal 20 of the plurality of outer terminals 20. More specifically, each of the plurality of inner electrodes 6 is bonded to a corresponding outer terminal 20 by a bonding portion 7. Examples of the material of the bonding portion 7 include solder.

The plurality of inner electrodes 6 are connected to the plurality of land electrodes 5 in a one-to-one manner, and are connected to the IC chip 2. Each of the plurality of inner electrodes 6 encompasses a corresponding land electrode 5 of the plurality of land electrodes 5 in plan view, as shown in FIG. 1. In the following, of the plurality of inner electrodes 6, the inner electrode 6 connected to the land electrode 51 may be referred to as an inner electrode 61, and the inner electrodes 6 connected to land electrodes 52˜55 may be referred to as inner electrodes 62˜66.

Each of the plurality of inner electrodes 6 includes a first portion 601 and a second portion 602. The first portion 601 of each of the plurality of inner electrodes 6 is larger in plan view than a corresponding land electrode 5 of the plurality of land electrodes 5. The first portion 601 of each of the plurality of inner electrodes 6 encompasses a corresponding land electrode 5 of the plurality of land electrodes 5 in plan view and has a plan-view shape along an outer edge 50 of the corresponding land electrode 5 in plan view. The second portion 602 of the inner electrode 6 protrudes from the first portion 601 toward the center of the IC chip 2 in plan view and partially overlaps in plan view with a corresponding outer terminal 20 of the plurality of outer terminals 20. The reason why the first portion 601 of each of the plurality of inner electrodes 6 encompasses a corresponding land electrode 5 of the plurality of land electrodes 5 in plan view is that in the method of manufacturing the electronic component 1 according to Embodiment 1, the plurality of land electrodes 5 are formed after the plurality of inner electrodes 6 have been formed.

(3) High-Frequency Module Provided with Electronic Component

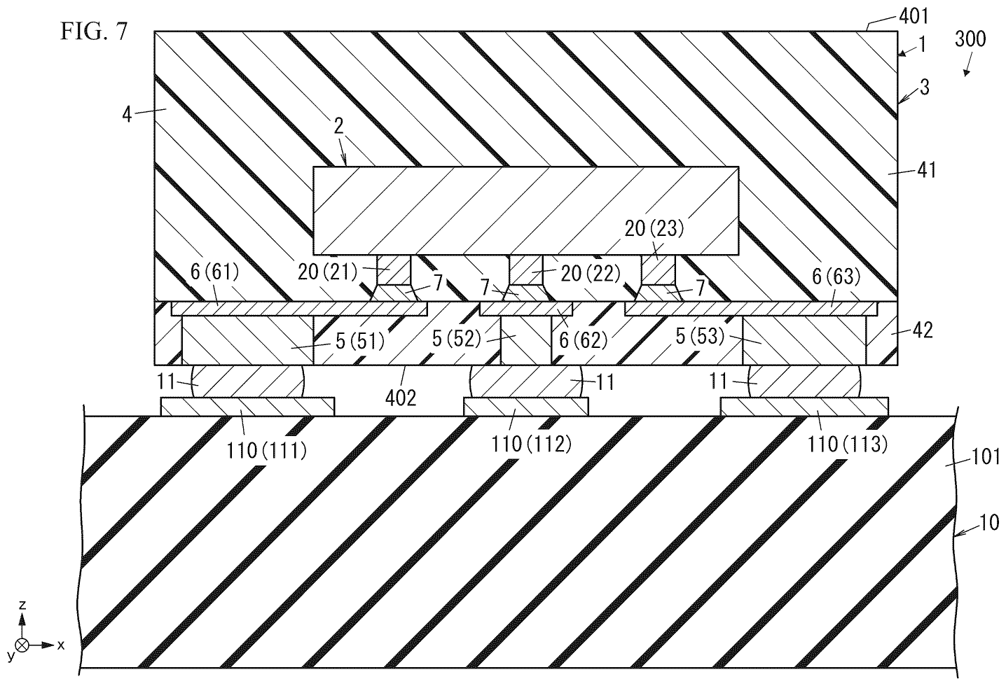

A high-frequency module 300, for example, includes the mounting board 10 and the electronic component 1, as shown in FIG. 7. The mounting board 10 has a main surface 101. The electronic component 1 is mounted on the main surface 101 of the mounting board 10.

The mounting board 10 has a plurality of pad electrodes 110 that correspond to the plurality of land electrodes 5 of the electronic component 1 in a one-to-one manner. The plurality of pad electrodes 110 includes a plurality of pad electrodes 111˜116 that correspond to the plurality of land electrodes 51˜56 in a one-to-one manner. Each of the plurality of land electrodes 5 of the electronic component 1 is bonded to a corresponding pad electrode 111 of the plurality of pad electrodes 111 by a bonding portion 11. The material of each bonding portion 11 is solder. In plan view from the predetermined direction, each of the plurality of pad electrodes 110 is larger than a corresponding land electrode 5 of the plurality of land electrodes 5 and encompasses the corresponding land electrode 5. In plan view from the predetermined direction, the area of the pad electrode 111 corresponding to the first land electrode is larger than the area of each of the five pad electrodes 112˜116 corresponding to the five second land electrodes. The plan-view shape of the pad electrode 111 is rectangular. The plan-view shape of the pad electrode 111 is different from the plan-view shape of the pad electrodes 112˜116.

The mounting board 10 is, for example, a printed wiring board. The mounting board 10 is not limited to a printed wiring board, but may be, for example, an LTCC (Low Temperature Co-fired Ceramics) substrate, an HTCC (High Temperature Co-fired Ceramics) substrate, a resin multilayer substrate or a components embedded substrate.

In the high-frequency module 300, a plurality of electronic components, including the electronic component 1, are mounted on the mounting board 10. The plurality of electronic components includes a power amplifier and a low-noise amplifier in addition to the electronic component 1. The power amplifier is connected, for example, to the selection terminal 201 of the electronic component 1. The power amplifier power-amplifies and outputs high-frequency signals (transmission signals). The low-noise amplifier is connected, for example, to the selection terminal 202 of the electronic component 1. The low-noise amplifier amplifies and outputs high-frequency signals (received signals).

The mounting board 10 has a plurality of outer connection terminals. The plurality of outer connection terminals includes, for example, an antenna terminal, a signal input terminal, a signal output terminal, and an input control terminal. The antenna terminal is connected to the common terminal 200 of the electronic component 1. The signal input terminal is connected, for example, to an input terminal of the power amplifier. The signal output terminal is connected to an output terminal of the low-noise amplifier, for example. The input control terminal is connected, for example, to the land electrode 51 of the electronic component 1.

### (4) Effects

In the electronic component 1 according to Embodiment 1, the plurality of land electrodes 5 includes one land electrode (first land electrode) and five land electrodes 52˜56 (second land electrodes), which are the remaining five land electrodes other than the land electrode 51. In the electronic component 1 according to Embodiment 1, the area of the land electrode 51 is larger than the area of each of the five land electrodes 52˜56 in plan view from the predetermined direction, and the plan-view shape of the land electrode 51 is different from the plan-view shapes of the five land electrodes 52˜56 in plan view from the predetermined direction. As a result, the electronic component 1 according to Embodiment 1 can improve the direction identifiability in the mounting process to the mounting board and can suppress the reduction of mounting strength to the mounting board.

More specifically, in the electronic component 1 according to Embodiment 1, since the area of the first land electrode is larger than the area of the five second land electrodes other than the first land electrode, and since the plan-view shape of the first land electrode is different from the plan-view shapes of the five second land electrodes, the first land can be identified from the side of the second main surface 402 among the first main surface 401 and the second main surface 402 of the resin portion 4. The mark 411 can be identified from the first main surface 401 side when the electronic component 1 is placed on a tape or tray before the electronic component 1 is sucked by a suction collet or other device in the mounting process. With the electronic component 1 of Embodiment 1, the first land electrode of the electronic component 1 can be identified in the mounting process while the electronic component 1 is being sucked by the suction collet, thus reducing the possibility of the electronic component 1 being mounted in the wrong direction to the mounting board. Further, since the area of the first land electrode is larger than that of the five second land electrodes other than the first land electrode and the plan-view shape of the first land electrode is different from the plan-view shapes of the five second land electrodes, the mounting strength of the first land electrode is apt to be relatively stronger than the mounting strength of each of the five second land electrodes, and the first land electrode becomes difficult to be detached from the mounting board.

In the electronic component 1 according to Embodiment 1, the land electrode 51 and the land electrode 53, through which high-frequency signals do not pass, are arranged adjacent to the land electrode 52 (common terminal 200), through which high-frequency signals pass. As a result, in the electronic component 1 according to Embodiment 1, it is easier to increase the distance between the land electrode 52 and the land electrode 54 (selection terminal 201), through which high-frequency signals pass, and it is easier to increase the distance between the land electrode 52 and the land electrode 56 (selection terminal 202), through which high-frequency signals pass. Thus, the electronic component 1 according to Embodiment 1 can reduce unnecessary parasitic capacitance generated between the land electrode 52 and the land electrode 54, and reduce unnecessary parasitic capacitance between the land electrode 52 and the land electrode 56. As a result, the electronic component 1 according to Embodiment 1 can improve high-frequency characteristics and reduce insertion loss.

The area of the pad electrode 111 corresponding to the land electrode 51 on the mounting board 10 on which the electronic component 1 is mounted is larger than the area of each of the five pad electrodes 112˜116 corresponding to the other five land electrodes 52˜56 in a one-to-one manner, and the parasitic capacitance (also called shunt capacitance) generated between the pad electrodes 110 and the ground becomes larger. However, in the electronic component 1, since the control terminal that does not need to pass high-frequency signals is allocated as the land electrode 51 among the plurality of land electrodes 5, even if the area of the land electrode 51 is larger than each of the other two land electrodes 52˜56, it is not necessary to consider the effect on high-frequency characteristics, which is an advantage.

In the electronic component 1 according to Embodiment 1, the first portion 601 of each of the plurality of inner electrodes 6 encompasses a corresponding land electrode 5 of the plurality of land electrodes 5 in plan view, and the second portion 602 of each of the plurality of inner electrodes 6 protrudes from the first portion 601 toward the center of the IC chip 2 in plan view. As a result, the electronic component 1 according to Embodiment 1 can make the shortest distance between adjacent inner electrodes 6 of the plurality of inner electrodes 6 longer, thereby reducing the parasitic capacitance generated between adjacent inner electrodes 6 and reducing the distribution capacitance between terminals generated between two land electrodes 5 that correspond between adjacent inner electrodes 6 in a one-to-one manner. In the example shown in FIG. 1, for example, the shortest distance G1 between the inner electrode 61 and the inner electrode 62 can be made longer, which can reduce the parasitic capacitance generated between the inner electrode 61 and the inner electrode 62, and the distribution capacitance between terminals generated between the land electrode 51 and the land electrode 52 can be reduced. For direct current and low frequency, the occurrence of the distribution capacitance between terminals is not a major problem, but it can be a problem for an electronic component for high frequency. In contrast, the electronic component 1 according to Embodiment 1 can make the shortest distance G1 between the inner electrode 61 and the inner electrode 62 longer, thereby reducing the distribution capacitance generated between the land electrode 52, through which high-frequency signals pass, and the ground, and increasing the return loss of the land electrode 52. Therefore, the electronic component 1 according to Embodiment 1 can improve matching performance and reduce the insertion loss of high-frequency signals passing through the land electrode 52.

In the electronic component 1 according to Embodiment 1, since the land electrode 51 with a large area among the three land electrodes 5 arranged along the long side 431 included in the outer edge 430 of the second main surface 402 of the resin portion 4 is not located between two land electrodes 52 and 53, the shortest distance between two adjacent inner electrodes 6 of the plurality of inner electrodes 6 can be made longer.

In addition, in the electronic component 1 according to Embodiment 1, the common terminal 200 of the SPDT-type switch is constituted by the land electrode 52 different from the land electrode 51, so that the matching performance and insertion loss can be improved in the path including the common terminal 200 and the selection terminal 201, and in the path including the common terminal 200 and the selection terminal 202, respectively.

### Embodiment 2

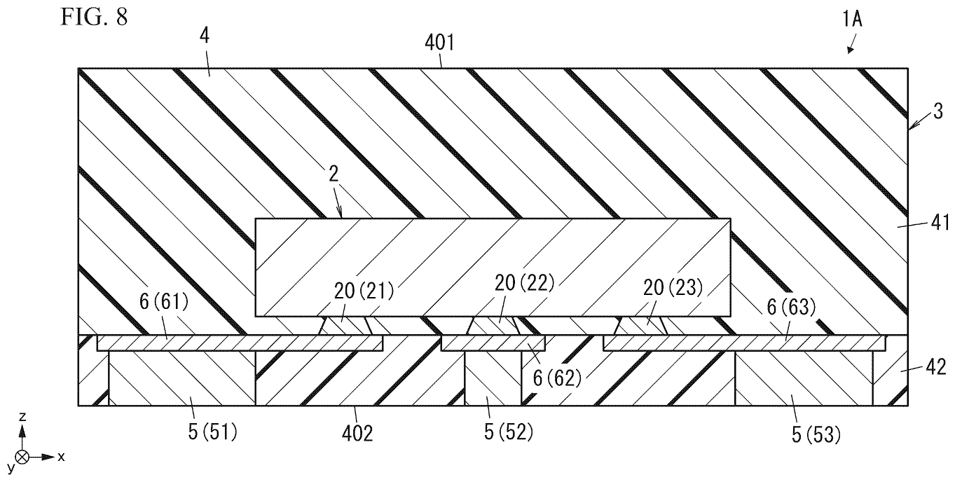

An electronic component 1A according to Embodiment 2 is described with reference to FIG. 8. With respect to the electronic component 1A according to Embodiment 2, the same components as those of the electronic component 1 according to Embodiment 1 (see FIGS. 1 to 5) are denoted by the same reference signs and the explanation thereof will be omitted.

### (1) Configuration

The electronic component 1A according to Embodiment 2 differs from the electronic component 1 according to Embodiment 1 in that a plurality of outer terminals 20 of an IC chip 2 are solder bumps. As a result, in the electronic component 1A, a portion of a first resin portion 41 interposed between the IC chip 2 and a second resin portion 42 is thinner than the electronic component 1.

In the electronic component 1A, the average particle diameter of the first filler in the first resin portion 41 is smaller than the average particle diameter of the second filler in the second resin portion 42.

### (2) Effects

Similar to the electronic component 1 according to Embodiment 1, in the electronic component 1A according to Embodiment 2, the area of a land electrode 51 is larger than the area of each of five land electrodes 52˜56 in plan view from the predetermined direction, and the plan-view shape of the land electrode 51 is different from the plan-view shapes of the five land electrodes 52˜56 in plan view from the predetermined direction. As a result, the electronic component 1A according to Embodiment 2 can improve the direction identifiability in the mounting process to the mounting board 10 and can suppress the reduction of mounting strength to the mounting board 10.

In the electronic component 1A according to Embodiment 2, since the average particle diameter of the first filler is smaller than the average particle diameter of the second filler, it is possible to suppress the generation of a gap between the IC chip 2 and the second resin portion 42 during the molding of the first resin portion 41, and to suppress the degradation of electrical insulation caused by the solder flash phenomenon (also called the solder splash phenomenon) occurring during the mounting process.

### Embodiment 3

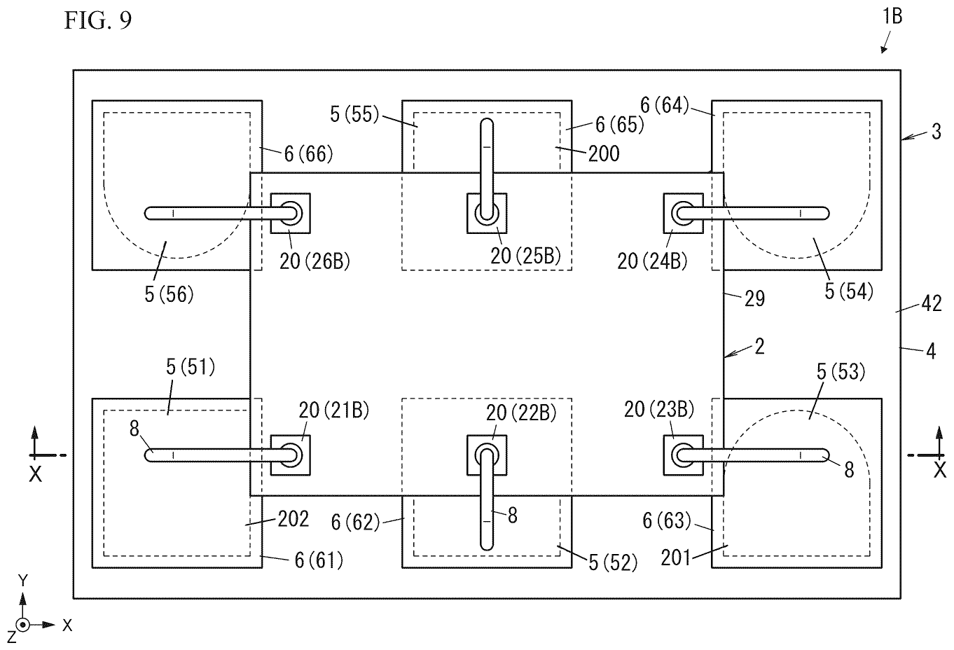

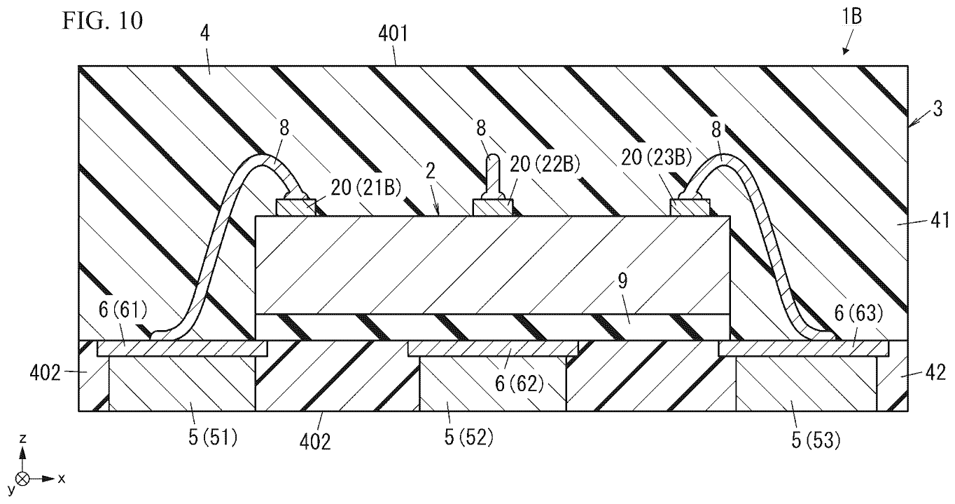

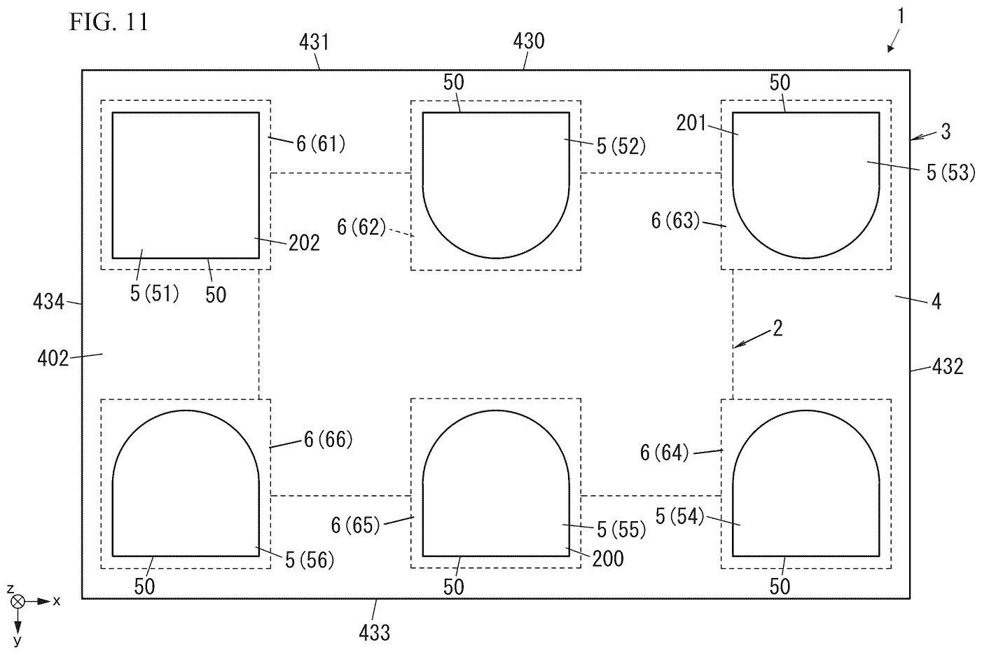

An electronic component 1B according to Embodiment 3 will be described with reference to FIGS. 9 to 12. With respect to the electronic component 1B according to Embodiment 3, the same components as those of the electronic component 1 according to Embodiment 1 (see FIGS. 1 to 5) are denoted by the same reference signs and the explanation thereof will be omitted. In FIG. 9, a first resin portion 41 is not shown.

### (1) Configuration of Electronic Component

In the electronic component 1B according to Embodiment 3, a plurality of outer terminals 20 (six in the example shown in FIG. 9) of an IC chip 2 are located on the opposite side of a second resin portion 42.

In the electronic component 1B, a land electrode 51, which is the first land electrode, constitutes a selection terminal 202. In the electronic component 1B, of five second land electrodes, a land electrode 55 constitutes a common terminal 200 and a land electrode 53 constitutes a selection terminal 201.

The plurality of outer terminals 20 in the electronic component 1B include two or more (three in the example shown in FIG. 9) high-frequency signal terminals and two or more (three in the example shown in FIG. 9) non-high-frequency signal terminals. In the example shown in FIG. 9, the two or more high-frequency signal terminals include three input/output terminals 21B, 23B and 25B. Each of the three input/output terminals 21B, 23B and 25B is a terminal through which high-frequency signals pass. In the example shown in FIG. 9, the input/output terminal 25B of the IC chip 2 is connected to the common terminal 200, the input/output terminal 23B of the IC chip 2 is connected to the selection terminal 201, and the input/output terminal 21B of the IC chip 2 is connected to the selection terminal 202. In the example shown in FIG. 9, the two or more non-high-frequency signal terminals include a power supply terminal 24B, a control terminal 26B, and a ground terminal 22B. The power supply terminal 24B is a terminal for inputting the power supply voltage from an external power supply to the IC chip 2. The control terminal 26B is a terminal for inputting, at the IC chip 2, a control signal from an external circuit to the IC chip 2.

The IC chip 2 is bonded to the second resin portion 42 via a bonding portion 9. The bonding portion 9 has electrical insulation properties. The material of the bonding portion 9 is, for example, DAF (Die Attach Film) for die bonding.

In the electronic component 1B, the plan-view shape of each of a plurality (six in the example shown in FIG. 9) of inner electrodes 6 has a rectangular shape (square shape in the example shown in FIG. 9) in plan view. In the electronic component 1B, the area of the plurality of inner electrodes 6 is the same.

In the electronic component 1B, each of the plurality (six in the example shown in FIG. 9) of outer terminals 20 is connected to a corresponding inner electrode 6 among the plurality (six in the example shown in FIG. 9) of inner electrodes 6 via a conductive wire 8 (bonding wire). Thus, the electronic component 1B includes six conductive wires 8. Each conductive wire 8 is, for example, an Au wire, an Al wire, a Cu wire, or a Pd-coated Cu wire.

In the electronic component 1B, the first resin portion 41 covers the IC chip 2 and the six conductive wires 8.

### (2) Circuit Configuration of Electronic Component

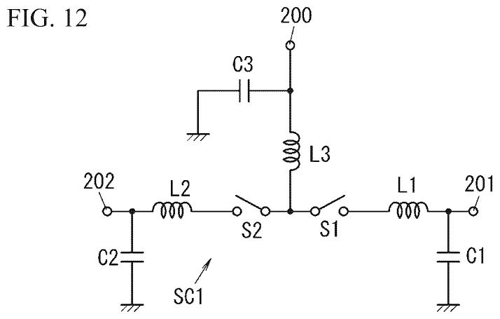

The equivalent circuit of a switch circuit SC1 of the electronic component 1B includes three inductors L1˜L3 and three capacitors C1˜C3, in addition to two switches S1 and S2, the common terminal 200 and the two selection terminals 201 and 202, as shown in FIG. 12.

The inductor L1 is connected between the switch S1 and the selection terminal 201. The inductor L2 is connected between the switch S2 and the selection terminal 202. The inductor L3 is connected between a connecting points of the switch S1 and the switch S2 and the common terminal 200.

The inductor L1 is the inductance component of the conductive wire 8 connecting the input/output terminal 23B of the IC chip 2 to an inner electrode 63. The inductor L2 is the inductance component of the conductive wire 8 connecting the input/output terminal 21B of the IC chip 2 to an inner electrode 61. The inductor L3 is the inductance component of the conductive wire 8 connecting the input/output terminal 25B of the IC chip 2 to an inner electrode 65.

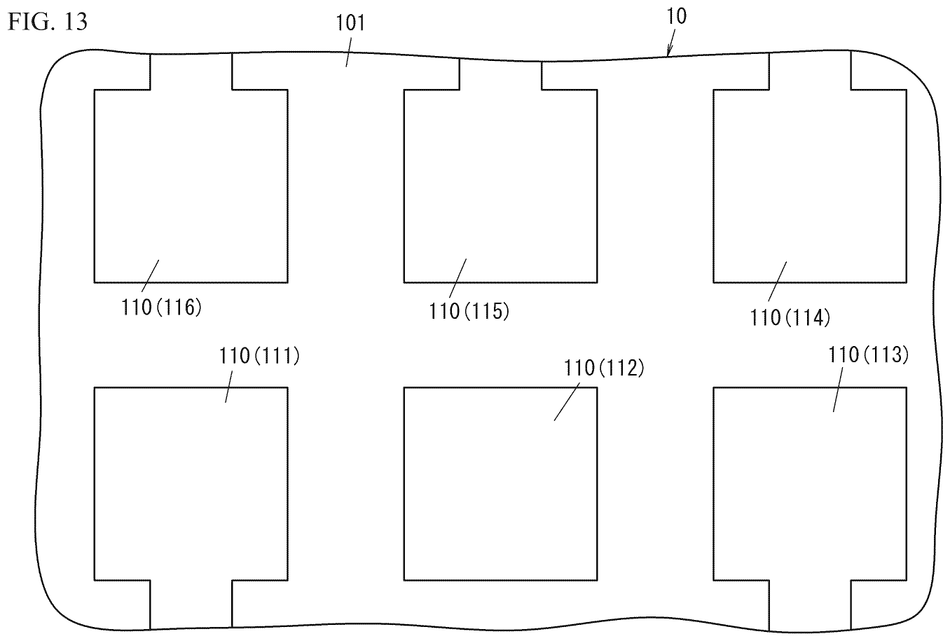

The capacitor C1 is a parasitic capacitance (shunt capacitance) generated between a pad electrode 113 connected to the land electrode 53 and the ground when the electronic component 1B is mounted on a mounting board 10 (see FIG. 13). The capacitor C2 is a parasitic capacitance (shunt capacitance) generated between a pad electrode 111 connected to the land electrode 51 and the ground when the electronic component 1B is mounted on the mounting board 10. The capacitor C3 is a parasitic capacitance (shunt capacitance) generated between a pad electrode 115 connected to the land electrode 55 and the ground when the electronic component 1B is mounted on the mounting board 10. The capacitor C1 functions as a capacitor to compensate for the inductance component of the inductor L1, i.e., as an impedance matching capacitor. The capacitor C2 functions as a capacitor to compensate for the inductance component of the inductor L2, i.e., as an impedance matching capacitor. The capacitor C3 functions as a capacitor to compensate for the inductance component of the inductor L3, i.e., as an impedance matching capacitor.

(3) High-Frequency Module Provided with Electronic Component

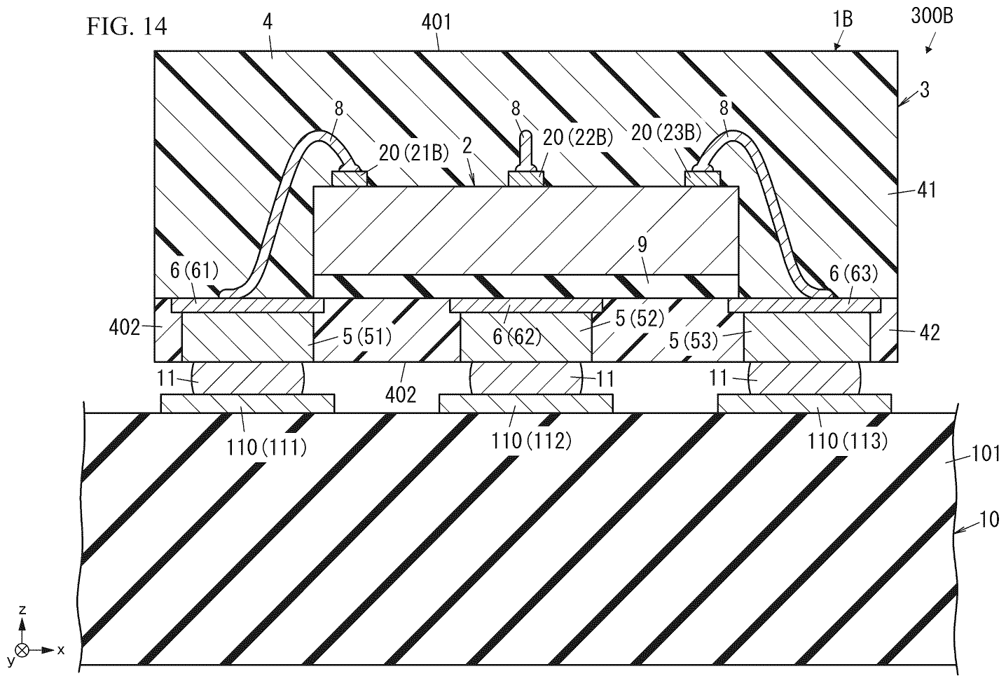

A high-frequency module 300B, for example, includes the mounting board 10 and the electronic component 1, as shown in FIG. 14. The electronic component 1B is mounted on the mounting board 10.

The mounting board 10 has a plurality of pad electrodes 110 that correspond to a plurality of land electrodes 5 of the electronic component 1B in a one-to-one manner. The plurality of pad electrodes 110 includes a plurality of pad electrodes 111˜116 that correspond to a plurality of land electrodes 51˜56 in a one-to-one manner. Each of the plurality of land electrodes 5 of the electronic component 1B is bonded to a corresponding pad electrode 111 of the plurality of pad electrodes 111 by a bonding portion 11. The material of each bonding portion 11 is solder. In plan view from the predetermined direction, each of the plurality of pad electrodes 110 is larger than a corresponding land electrode 5 of the plurality of land electrodes 5 and encompasses the corresponding land electrode 5. In plan view from the predetermined direction, the six pad electrodes 111˜116 have the same area. The plan-view shape of each of the six pad electrodes 111˜116 is rectangular (square in the example shown in FIG. 13). The plan-view shapes of the six pad electrodes 111˜116 are the same.

The mounting board 10 is, for example, a printed wiring board. The mounting board 10 is not limited to a printed wiring board, but may be, for example, an LTCC substrate, an HTCC substrate, a resin multilayer substrate, or a components embedded substrate.

Similar to the high-frequency module 300 according to Embodiment 1, in the high-frequency module 300B, a plurality of electronic components including the electronic component 1B are mounted on the mounting board 10.

Similar to the mounting board 10 of the high-frequency module 300 according to Embodiment 1, the mounting board 10 has a plurality of outer connection terminals.

### (4) Effects

In the electronic component 1B according to Embodiment 3, the area of the land electrode 51 is larger than the area of each of the five land electrodes 52˜56 in plan view from the predetermined direction, and the plan-view shape of the land electrode 51 is different from the plan-view shapes of the five land electrodes 52˜56 in plan view from the predetermined direction. As a result, the electronic component 1B according to Embodiment 3 can improve the direction identifiability in the mounting process to the mounting board 10 and can suppress the reduction of mounting strength to the mounting board 10.

The above Embodiments 1 to 3 and the like are only one of the various embodiments of the present disclosure. The above embodiments and the like may be modified in various ways depending on the design and the like, as long as the possible benefit of the present disclosure can be achieved.

### (Variation 1)

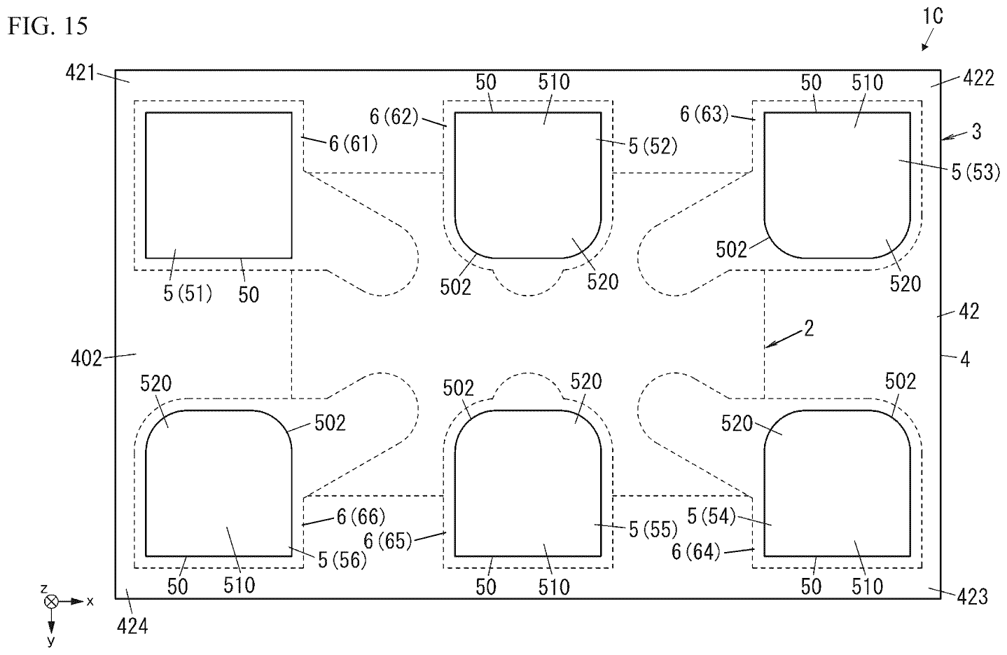

In an electronic component 1C according to Variation 1 of Embodiment 1, as shown in FIG. 15, the shape of each of five land electrodes 52˜56 is different from that of the five land electrodes 52˜56 in the electronic component 1 according to Embodiment 1.

The five land electrodes 52˜56 in the electronic component 1C according to Variation 1 differ from the five land electrodes 52˜56 in the electronic component 1 according to Embodiment 1 in that each of two apexes of the square has an arc-shaped portion 502.

### (Variation 2)

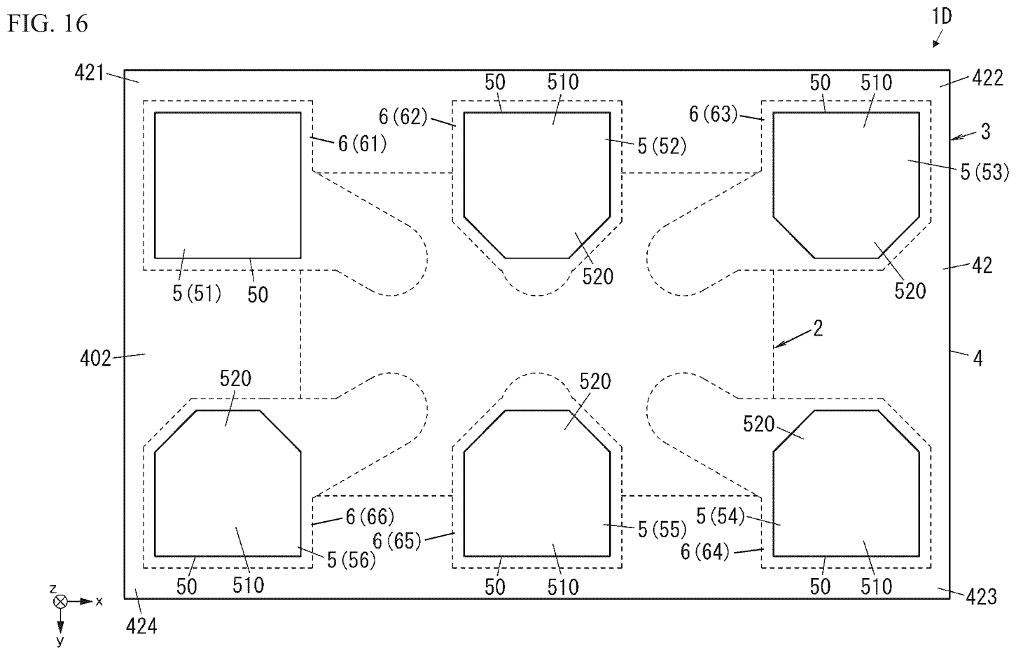

An electronic component 1D according to Variation 2 of Embodiment 1 differs from the electronic component 1 according to Embodiment 1 in that the plan-view shape of each of a plurality of land electrodes 52˜56 is a hexagonal shape in plan view, as shown in FIG. 16. In each of the plurality of land electrodes 52˜56, a first portion 510 has a non-square rectangular shape and a second portion 520 has a trapezoidal shape.

### (Variation 3)

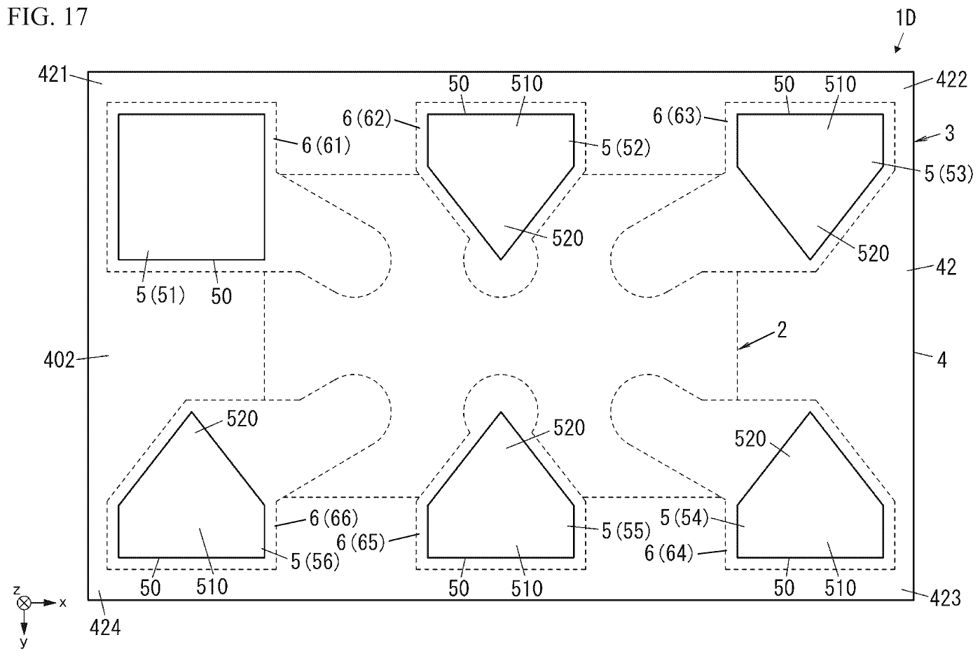

An electronic component 1E according to Variation 3 of Embodiment 1 differs from the electronic component 1 according to Embodiment 1 in that the plan-view shape of each of a plurality of land electrodes 52˜56 is a pentagonal shape in plan view, as shown in FIG. 17. In each of the plurality of land electrodes 52˜56, a first portion 510 has a non-square rectangular shape and a second portion 520 has a triangular shape.

### (Variation 4)

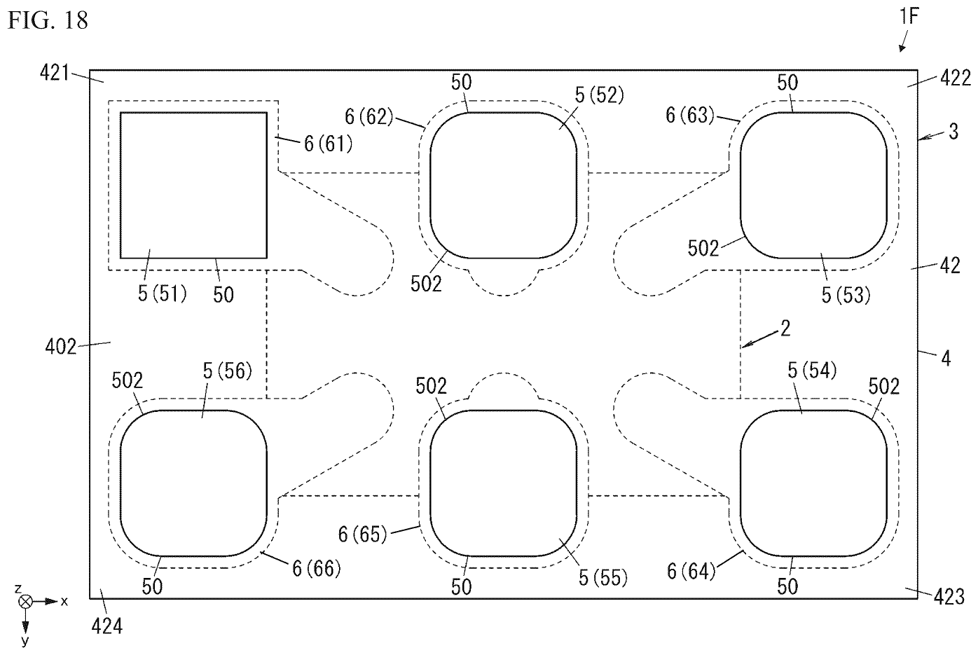

As shown in FIG. 18, the shape of each of five land electrodes 52˜56 in an electronic component 1F according to Variation 4 of Embodiment 1 is different from the shapes of the five land electrodes 52˜56 in the electronic component 1 according to Embodiment 1.

The five land electrodes 52˜56 in the electronic component 1F according to Variation 4 of Embodiment 1 differ from the five land electrodes 52˜56 in the electronic component 1 according to Embodiment 1 in that each of the four apexes of the square has an arc-shaped portion 502.

### (Variation 5)

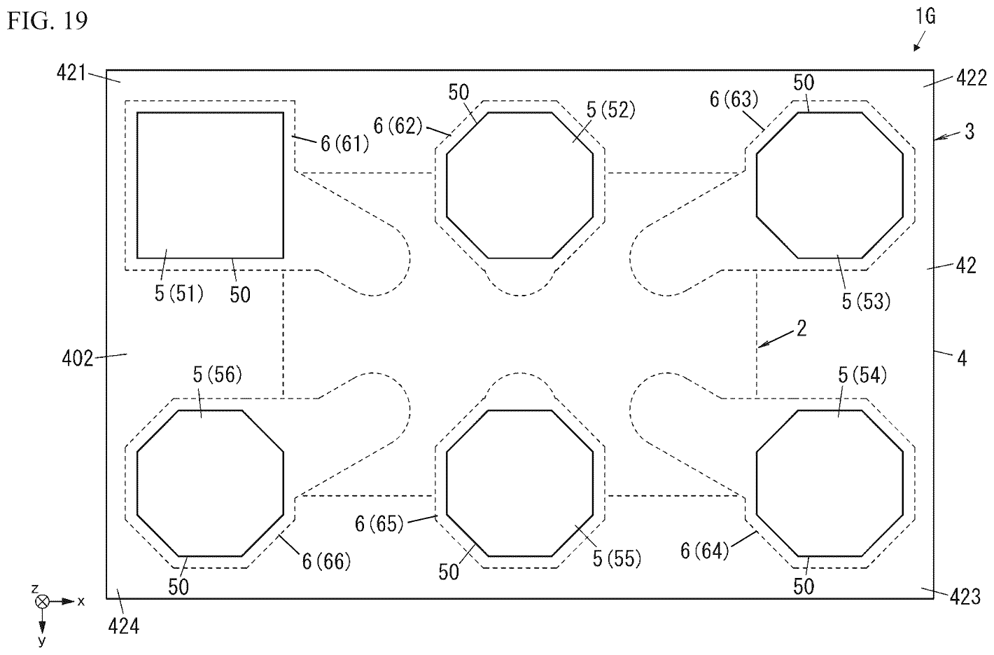

An electronic component 1G according to Variation 5 of Embodiment 1 differs from the electronic component 1 according to Embodiment 1 in that the plan-view shape of each of five land electrodes 52˜56 is an octagonal shape in plan view, as shown in FIG. 19.

### (Variation 6)

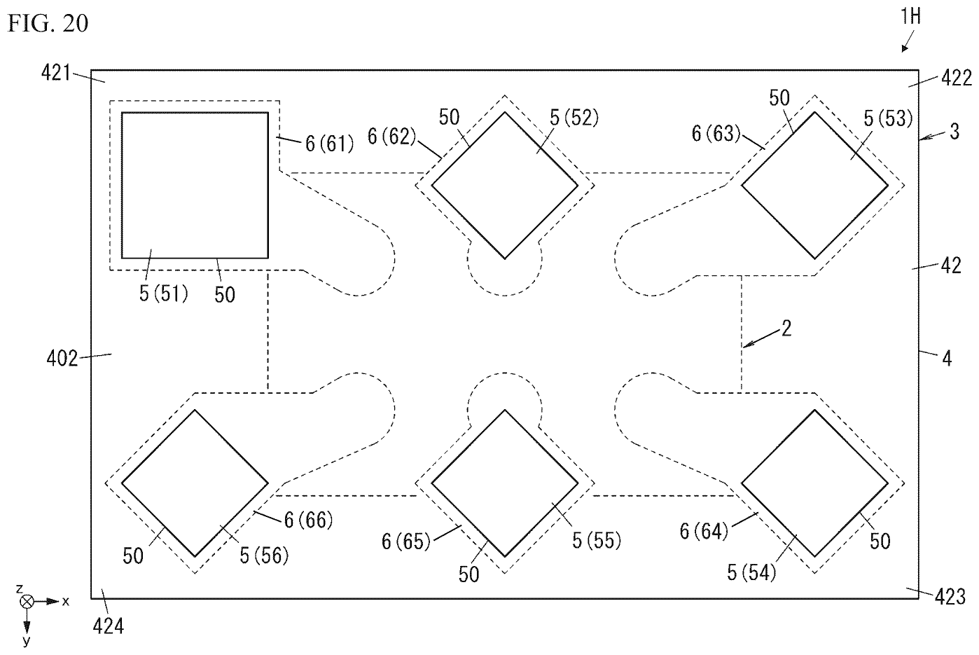

As shown in FIG. 20, an electronic component 1H according to Variation 6 of Embodiment 1 differs from the electronic component 1 according to Embodiment 1 in that the plan-view shape of each of five land electrodes 52˜56 is a square shape, and one diagonal of the square shape is parallel to long sides 431 and 433 of an outer edge 430 of a second main surface 402 of a resin portion 4, and the other diagonal is parallel to short sides 432 and 434.

### (Variation 7)

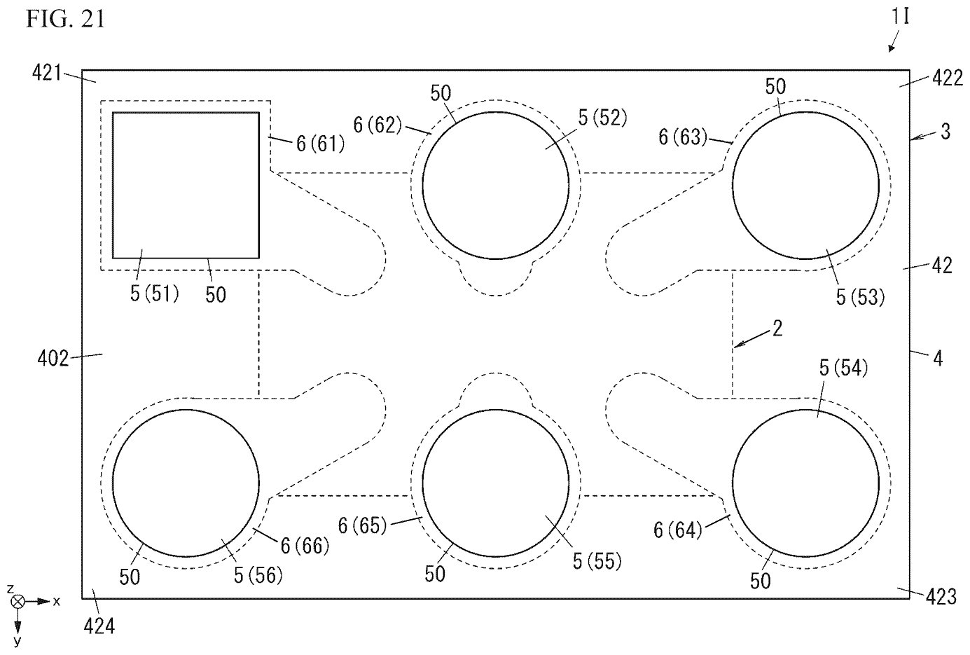

An electronic component 1I according to Variation 7 of Embodiment 1 differs from the electronic component 1 according to Embodiment 1 in that the plan-view shape of each of five land electrodes 52˜56 is circular, as shown in FIG. 21.

### (Variation 8)

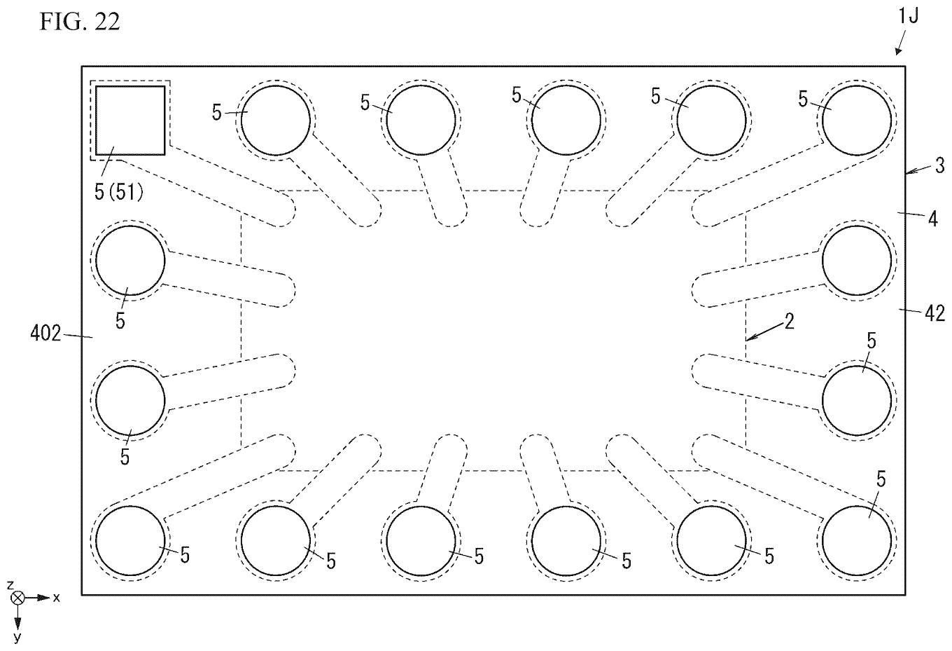

As shown in FIG. 22, an electronic component 1J according to Variation 8 of Embodiment 1 differs from the electronic component 1 according to Embodiment 1 in that, it includes sixteen land electrodes 5, and the sixteen land electrodes 5 include one land electrode 51 (first land electrode) and fifteen land electrodes 5 (second land electrode) other than the land electrode 51. The electronic component 1 according to Embodiment 1 is an SPDT-type switch for high frequency, but the electronic component 1J according to Variation 8 is not an SPDT-type switch, but is, for example, a switch with one common terminal and N (N is an integer of 3 or more) selection terminals, or a switch with N common terminals and N selection terminals.

### (Variation 9)

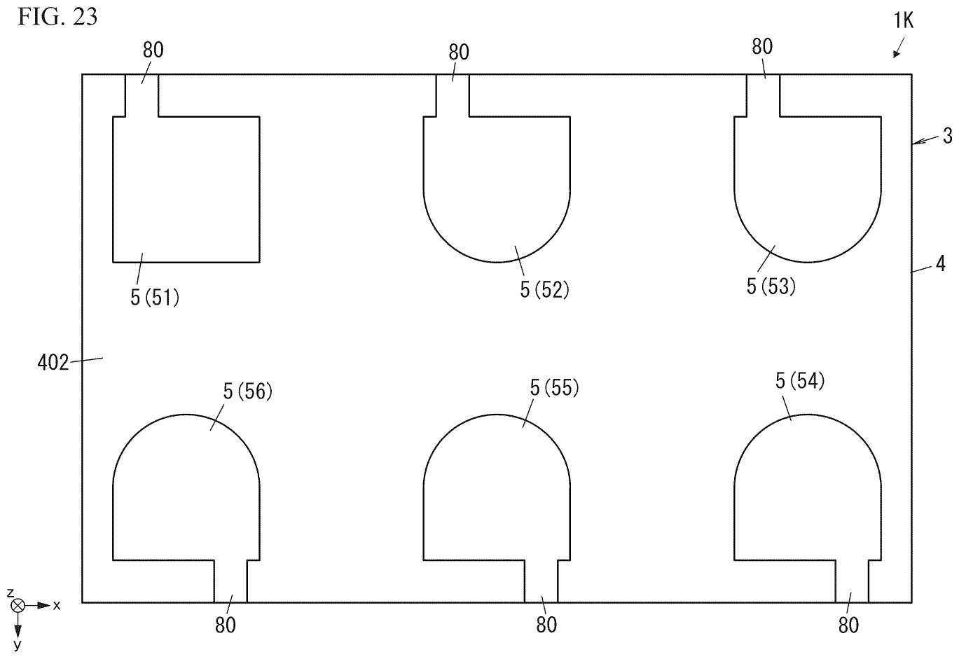

An electronic component 1K according to Variation 9 of Embodiment 1 differs from the electronic component 1 according to Embodiment 1 in that it includes six protrusions 80 exposed from a second main surface 402 of a resin portion 4 in plan view from the predetermined direction, as shown in FIG. 23. The six protrusions 80 correspond to six land electrodes 5 in a one-to-one manner, and project from outer edges of the corresponding land electrodes 5 toward an outer edge 430 of the second main surface 402 of the resin portion 4. The width of the protrusion 80 is narrower than the width of the land electrode 5. Each of the six land electrodes 5 does not include the protrusion 80. When the six land electrodes 5 are formed from a single lead frame, the protrusion 80 is a part of the lead frame. In other words, the protrusion 80 is formed by cutting, in the lead frame, a connecting portion connecting the land electrode 5 and a frame portion from the frame portion.

### (Variation 10)

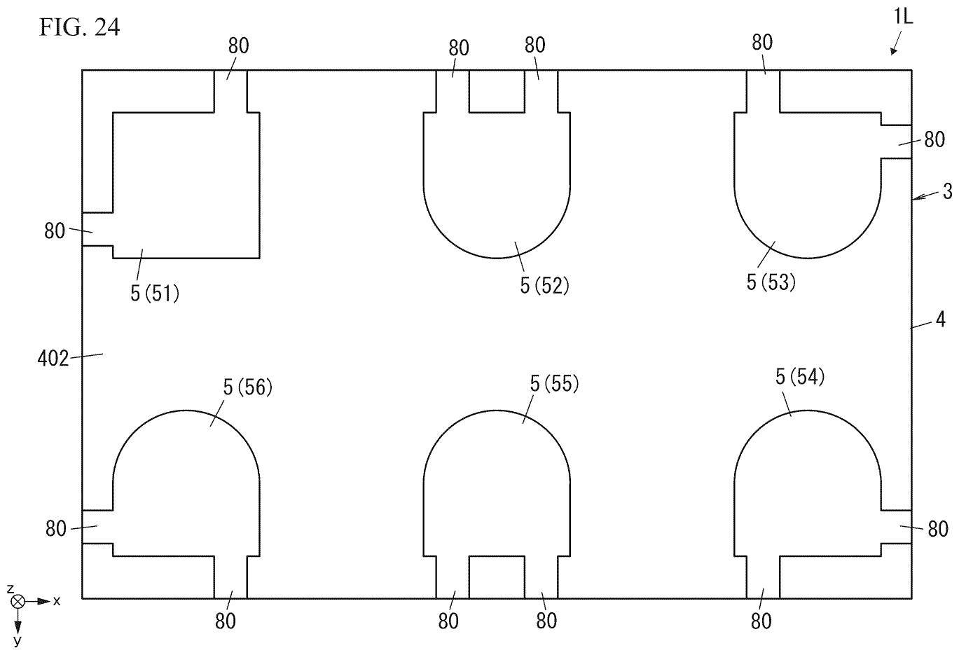

An electronic component 1L according to Variation 10 of Embodiment 1 differs from the electronic component 1K according to Variation 9 of Embodiment 1 in that two protrusions 80 are connected to each of six land electrodes 5, as shown in FIG. 24. Each of the six land electrodes 5 does not include the two protrusions 80. When the six land electrodes 5 are formed from a single lead frame, the twelve protrusions 80 are a part of the lead frame. In other words, the twelve protrusions 80 are formed by cutting, in the lead frame, twelve connecting portions connecting the six land electrodes 5 and a frame portion from the frame portion.

### (Other Variations)

For example, in the electronic components 1 and 1A˜1L, the plurality of land electrodes 5 may include land electrodes 5 that are not electrically connected to the circuit of the IC chip 2. For example, the first land electrode (land electrode 51) may be a land electrode that is not electrically connected to the circuit of the IC chip 2.

In the electronic components 1 and 1A˜1L, the plurality of land electrodes 5 is not limited to the case where the plurality of land electrodes 5 includes one first land electrode and five or more second land electrodes, but include a case where the plurality of land electrodes 5 includes one first land electrode and three or more second land electrodes.

In the electronic component 1, the first portion 601 of each of the plurality of inner electrodes 6 is larger than the overlapping land electrode 5 in the predetermined direction, but the first portion 601 may be smaller than the land electrode 5. In such a case, each of the plurality of land electrodes 5 encompasses a corresponding first portion 601 of the plurality of inner electrodes 6 in plan view from the predetermined direction.

The electronic components 1C˜1L according to each of the above variations also have the same effects as those of the electronic component 1 for Embodiment 1.

The electronic component for high frequency according to the present disclosure is not limited to an SPDT-type switch, but may also be an antenna changeover switch, a switchplexer, an electronic component including a switch and a low-noise amplifier, an electronic component including a low pass filter and an RF switch, an electronic component or an amplifier including a band pass filter and an RF switch.

The electronic component according to the present disclosure may be configured so that the package 3 covers the IC chip 2 and a chip different from the IC chip 2. Example of the chip different from the IC chip 2 include an acoustic wave filter (for example, SAW filter).

### (Aspects)

The present description discloses the following aspects.

An electronic component (1; 1A; 1B; 1C; 1D; 1E; 1F; 1G; 1H; 1I; 1J; 1K; 1L) according to a first aspect includes a IC chip (2) and a package (3). The package (3) covers the IC chip (2). The package (3) includes a resin portion (4) and a plurality of land electrodes (5). The resin portion (4) has a first main surface (401) and a second main surface (402) facing each other in the predetermined direction and covers the IC chip (2). The plurality of land electrodes (5) are exposed from the second main surface (402) of the resin portion (4). The plurality of land electrodes (5) includes one first land electrode (land electrode 51) and three or more second land electrodes (land electrodes 52˜56), which are the remaining land electrodes (5) other than the first land electrode. The area of the first land electrode is larger than the area of each of the three or more second land electrodes in plan view from the predetermined direction. The plan-view shape of the first land electrode is different from the plan-view shapes of the three or more second land electrodes in plan view from the predetermined direction.

According to this aspect, it is possible to improve the direction identifiability in the mounting process to a mounting board (10) and to suppress the reduction of the mounting strength to the mounting board (10).

In an electronic component (1; 1A; 1B; 1C; 1D; 1E; 1F; 1G; 1H; 1I; 1J; 1K; 1L) according to a second aspect, in the first aspect, the plurality of land electrodes (5) are electrically connected to the IC chip (2).

In an electronic component (1; 1A; 1B; 1C; 1D; 1E; 1F; 1G; 1H; 1I; 1J; 1K; 1L) according to a third aspect, in the first aspect, the first land electrode (land electrode 51) is electrically connected to the IC chip (2).

According to this aspect, the mounting strength of the first land electrode, which is electrically connected to the IC chip (2), can be improved.

In an electronic component (1; 1A; 1B; 1C; 1D; 1E; 1F; 1G; 1H; 1I; 1J; 1K; 1L) according to a fourth aspect, in any one of the first to three aspects, the plan-view shape of three or more second land electrodes (land electrodes 52˜56) is the same as each other.

According to this aspect, it becomes easier to identify the first land electrode.

In an electronic component (1; 1A; 1B; 1C; 1D; 1E; 1F; 1G; 1H; 1I; 1J; 1K; 1L) according to a fifth aspect, in any one of the first to fourth aspects, the resin portion (4) is rectangular in plan view. The first land electrode is arranged in any one of four corner portions (421˜424) of the second main surface (402) of the resin portion (4).

According to this aspect, by defining the first land electrode as a No. 1 terminal, it is possible to easily identify the No. 1 terminal in a corner portion set as the standard in the industry.

In an electronic component (1; 1A; 1B; 1C; 1D; 1E; 1F; 1G; 1H; 1I; 1J; 1K; 1L) according to a sixth aspect, in any one of the first to fifth aspects, the plan-view shape of the first land electrode (land electrode 51) is rectangular. The plan-view shape of each of the three or more second land electrodes (land electrodes 52˜56) has an arc-shaped portion (502).

According to this aspect, it becomes easier to identify the first land electrode.

In an electronic component (1; 1A; 1B; 1C; 1D; 1E; 1F; 1G; 1H; 1I; 1J; 1K; 1L) according to a seventh aspect, in any one of the first to sixth aspects, each of the three or more second land electrodes (land electrodes 52˜56) includes a first portion (510) and a second portion (520). The first portion (510) is rectangular in plan view. The width of the second portion (520) becomes narrower as it goes away from the first portion (510) in plan view. In each of the three or more second land electrodes (land electrodes 52˜56), the first portion (510) and the second portion (520) are arranged from the side of an outer edge (430) of the second main surface (402) of the resin portion (4) in the order of the first portion (510) and second portion (520).

In an electronic component (1; 1A; 1B; 1C; 1D; 1E; 1F; 1G; 1H; 1I; 1J; 1K; 1L) according to an eighth aspect, in the seventh aspect, the package (3) further includes a plurality of inner electrodes (6) arranged in the resin portion (4). The plurality of inner electrodes (6) are connected to the plurality of land electrodes (5) in a one-to-one manner, and are connected to the IC chip (2). Each of the plurality of land electrodes (5) is encompassed in plan view by a corresponding inner electrode (6) of the plurality of inner electrodes (6).

In an electronic component (1; 1A; 1B; 1C; 1D; 1E; 1F; 1G; 1H; 1I; 1J; 1K; 1L) according to a ninth aspect, in the eighth aspect, the IC chip (2) has a plurality of outer terminals (20). Each of the plurality of inner electrodes (6) includes a first portion (601) and a second portion (602). The first portion (601) of each of the plurality of inner electrodes (6) encompasses a corresponding land electrode (5) of the plurality of land electrodes (5) in plan view and has a plan-view shape along an outer edge (50) of the corresponding land electrode (5) in plan view. The second portion (602) protrudes from the first portion (601) in plan view toward the center of the IC chip (2) and partially overlaps in plan view with a corresponding outer terminal (20) of the plurality of outer terminals (20).

According to this aspect, the shortest distance (G1) between adjacent inner electrodes (6) of the plurality of inner electrodes (6) can be made longer, which can reduce the distribution capacitance between terminals.

In an electronic component (1; 1A; 1C; 1D; 1E; 1F; 1G; 1H; 1I; 1J; 1K; 1L) according to a tenth aspect, in any one of the first to eighth aspects, the IC chip (2) has a plurality of outer terminals (20). The plurality of outer terminals (20) include two or more high-frequency signal terminals and two or more non-high-frequency signal terminals. Each of the two or more high-frequency signal terminals is an input/output terminal (22, 24 or 26) of high-frequency signals. Each of the two or more non-high-frequency signal terminals is a power supply terminal (23) or a control terminal (21) or a ground terminal (25). The first land electrode (land electrode 51) is connected to one non-high-frequency signal terminal of the two or more non-high-frequency signal terminals.

According to this aspect, it is possible to improve the mounting strength of the first land through which high-frequency signals do not pass.

In an electronic component 1B according to an eleventh aspect, in any one of the first to eighth aspects, the IC chip (2) has a plurality of outer terminals (20B). The plurality of outer terminals (20B) includes two or more high-frequency signal terminals and two or more non-high-frequency signal terminals. Each of the two or more high-frequency signal terminals is an input/output terminal (21B, 23B or 25B) of high-frequency signals. Each of the two or more non-high-frequency signal terminals is a power supply terminal (24B) or a control terminal (26B) or a ground terminal (22B). The first land electrode is connected to one high-frequency signal terminal of the two or more high-frequency signal terminals.

According to this aspect, it is possible to improve the mounting strength of the first land electrode through which high-frequency signals pass.

In an electronic component (1; 1A; 1C; 1D; 1E; 1F; 1G; 1H; 1I; 1J; 1K; 1L) according to a twelfth aspect, in any one of the first to eleventh aspects, the resin portion (4) includes a first resin portion (41) and a second resin portion (42). The first resin portion (41) has the first main surface 401 and covers the IC chip (2). The second resin portion (42) has the second main surface (402), and the plurality of inner electrodes (6) and the plurality of land electrodes (5) are arranged in the second resin portion (42). The first resin portion (41) includes a first resin and a first filler. The second resin portion (42) includes a second resin and a second filler. The average particle diameter of the second filler is smaller than the average particle diameter of the first filler.

In an electronic component (1B) according to a thirteenth aspect, in any one of the first to eleven aspects, the resin portion (4) includes a first resin portion (41) and a second resin portion (42). The first resin portion (41) has the first main surface (401) and covers the IC chip (2). The second resin portion (42) has the second main surface (402), and the plurality of inner electrodes (6) and the plurality of land electrodes (5) are arranged in the second resin portion (42). The first resin portion (41) includes a first resin and a first filler. The second resin portion (42) includes a second resin and a second filler. The average particle diameter of the first filler is smaller than the average particle diameter of the second filler.

According to this aspect, it is possible to suppress the generation of a void between the IC chip (2) and the second resin portion (42) during the molding of the first resin portion (41), and to suppress the degradation of electrical insulation caused by the solder flash phenomenon (also called solder splash phenomenon) in the mounting process.

What is claimed is:

1. An electronic component comprising:
an IC chip; and
a package covering the IC chip,
wherein
the package includes
a resin portion having a first main surface and a second main surface facing each other in a predetermined direction and covering the IC chip, and
a plurality of land electrodes exposed from the second main surface of the resin portion,
the plurality of land electrodes includes
one first land electrode, and
three or more second land electrodes being remaining land electrodes other than the first land electrode,
an area of the first land electrode is larger than the area of each of the three or more second land electrodes in a plan view from the predetermined direction, and
a plan-view shape of the first land electrode is different from plan-view shapes of the three or more second land electrodes in the plan view from the predetermined direction.

2. The electronic component according to claim 1, wherein the plurality of land electrodes is electrically connected to the IC chip.

3. The electronic component according to claim 1, wherein the first land electrode is electrically connected to the IC chip.

4. The electronic component according to claim 1, wherein the plan-view shapes of the three or more second land electrodes are same as each other.

5. The electronic component according to claim 1, wherein
the resin portion is rectangular in a plan view, and
the first land electrode is arranged in any one of four corner portions of the second main surface of the resin portion.

6. The electronic component according to claim 1, wherein
the plan-view shape of the first land electrode is rectangular, and
the plan-view shape of each of the three or more second land electrodes has an arc-shaped portion.

7. The electronic component according to claim 1, wherein
each of the three or more second land electrodes includes
a rectangular first portion in the plan view, and
a second portion having a narrower width as being farther away from the first portion in the plan view, and
in each of the three or more second land electrodes, the first portion and the second portion are arranged in an order of the first portion and the second portion when viewed from an outer edge of the second main surface of the resin portion.

8. The electronic component according to claim 7, wherein
the package further includes
a plurality of inner electrodes arranged in the resin portion,
the plurality of inner electrodes is connected to the plurality of land electrodes in a one-to-one manner, and is connected to the IC chip, and
each of the plurality of land electrodes is encompassed in a plan view by a corresponding inner electrode of the plurality of inner electrodes.

9. The electronic component according to claim 8, wherein
the IC chip has a plurality of outer terminals, and
each of the plurality of inner electrodes includes
a first portion encompassing a corresponding land electrode of the plurality of land electrodes in the plan view and having a plan-view shape along an outer edge of the corresponding land electrode in the plan view, and
a second portion protruding from the first portion in the plan view toward a center of the IC chip and partially overlapping in the plan view with a corresponding outer terminal of the plurality of outer terminals.

10. The electronic component according to claim 1, wherein
the IC chip has a plurality of outer terminals,
the plurality of outer terminals includes
two or more high-frequency signal terminals, and
two or more non-high-frequency signal terminals,
each of the two or more high-frequency signal terminals is an input/output terminal of high-frequency signals,
each of the two or more non-high-frequency signal terminals is a power supply terminal or a control terminal or a ground terminal, and
the first land electrode is connected to one non-high-frequency signal terminal of the two or more non-high-frequency signal terminals.

11. The electronic component according to claim 1, wherein
the IC chip has a plurality of outer terminals,
the plurality of outer terminals includes
two or more high-frequency signal terminals, and
two or more non-high-frequency signal terminals,
each of the two or more high-frequency signal terminals is an input/output terminal of high-frequency signals,
each of the two or more non-high-frequency signal terminals is a power supply terminal or a control terminal or a ground terminal, and
the first land electrode is connected to one high-frequency signal terminal of the two or more high-frequency signal terminals.

12. The electronic component according to claim 8, wherein
the resin portion includes
a first resin portion having the first main surface and covering the IC chip, and
a second resin portion having the second main surface, wherein the plurality of inner electrodes and the plurality of land electrodes are arranged in the second resin portion,
the first resin portion includes a first resin and a first filler,
the second resin portion includes a second resin and a second filler, and
an average particle diameter of the second filler is smaller than an average particle diameter of the first filler.

13. The electronic component according to claim 8, wherein
the resin portion includes
a first resin portion having the first main surface and covering the IC chip, and
a second resin portion having the second main surface, wherein the plurality of inner electrodes and the plurality of land electrodes are arranged in the second resin portion,
the first resin portion includes a first resin and a first filler,
the second resin portion includes a second resin and a second filler, and
an average particle diameter of the first filler is smaller than an average particle diameter of the second filler.

14. The electronic component according to claim 2, wherein the plan-view shapes of the three or more second land electrodes are same as each other.

15. The electronic component according to claim 2, wherein
the resin portion is rectangular in a plan view, and
the first land electrode is arranged in any one of four corner portions of the second main surface of the resin portion.

16. The electronic component according to claim 2, wherein
the plan-view shape of the first land electrode is rectangular, and
the plan-view shape of each of the three or more second land electrodes has an arc-shaped portion.

17. The electronic component according to claim 2, wherein
each of the three or more second land electrodes includes
a rectangular first portion in the plan view, and
a second portion having a narrower width as being farther away from the first portion in the plan view, and
in each of the three or more second land electrodes, the first portion and the second portion are arranged in an order of the first portion and the second portion when viewed from an outer edge of the second main surface of the resin portion.

18. The electronic component according to claim 2, wherein
the IC chip has a plurality of outer terminals,
the plurality of outer terminals includes
two or more high-frequency signal terminals, and
two or more non-high-frequency signal terminals,
each of the two or more high-frequency signal terminals is an input/output terminal of high-frequency signals,
each of the two or more non-high-frequency signal terminals is a power supply terminal or a control terminal or a ground terminal, and
the first land electrode is connected to one non-high-frequency signal terminal of the two or more non-high-frequency signal terminals.

19. The electronic component according to claim 2, wherein
the IC chip has a plurality of outer terminals,
the plurality of outer terminals includes
two or more high-frequency signal terminals, and
two or more non-high-frequency signal terminals,
each of the two or more high-frequency signal terminals is an input/output terminal of high-frequency signals,
each of the two or more non-high-frequency signal terminals is a power supply terminal or a control terminal or a ground terminal, and
the first land electrode is connected to one high-frequency signal terminal of the two or more high-frequency signal terminals.
